(19) United States
(12) Patent Application Publication
(10) Pub. No.: US 2009/0231807 A1
(43) Pub. Date: Sep. 17, 2009

(54) Waterproof Ventilated Display Enclosure

(76) Inventor: Michael F. Bouissiere, Yorba Linda, CA (US)

Correspondence Address: Altera Law Group, LLC, 220 S 6 St Suite 1700, Minneapolis, MN, 55402, US

(21) Appl. No.: 12/047,390

(22) Filed: Mar. 13, 2008

(51) Int. Cl. H05K 7/20; A47B 81/00; H05K 7/18; H05K 5/02

(52) U.S. Cl. 361/690; 312/101; 361/699; 361/689

(57) ABSTRACT

A waterproof ventilated enclosure for housing equipment is disclosed having the ability to channel water thru the enclosure without touching the equipment and further with the ability to provide active or passive ventilation to the equipment. In the preferred case, the equipment is a video monitor which may be mounted in an outdoor environment. The enclosure includes structures which separate liquid from air through the same or related ports, but prevents commingling.

### CROSS-REFERENCE TO RELATED APPLICATIONS

Not Applicable

### BACKGROUND

1. Field of the Invention

The present disclosure is directed to the field of waterproof ventilated enclosures for equipment in general, and more particularly to enclosures for equipment sensitive to liquid rain and requires ventilation to expel heat generated by the equipment.

Almost all equipment must be protected from rain or other precipitation. Likewise most equipment generates heat or is sensitive to heat and thus its temperature must be controlled by active or passive ventilation. The combination of these two requirements has become important for visual display screens, for example, which must be placed in outdoor environments. Flat screens in particular are important for outdoor signage but only if waterproofing and heat management can be provided.

The problem is not new to flat screens however, CRTs have similar problems and there has been a long felt need to find a relatively inexpensive solution to these problems. Solutions which solve waterproofing by effectively sealing the equipment from water are unacceptable as they do not solve the heat management problem. Solutions which solve the heat management problem by providing ducted air-conditioning to the equipment are expensive and often noisy. For purposes of mass installation of video screens outdoors, for example, these solutions would have to be considered failures and they make the use of such equipment outdoors prohibitively expensive.

A further problem in the construction of a suitable enclosure is the need to provide an universal enclosure which will permit installation of the equipment in different orientations (for example horizontally or vertically—“letter” or “landscape” orientation), without the need to construct different types for different orientations.

In the present disclosure, there are solutions which solve these problems and can be produced relatively cheaply.

### BRIEF SUMMARY

The following is a summary provided to help the reader quickly understand some of the points of the disclosure. It is not a definition of the invention and no substitute for reading the entire disclosure to understand the invention.

In this application there is disclosed a water impervious ventilated enclosure having a top, bottom and sides, and a space for equipment therein having a support frame for receiving equipment requiring protection from liquid contact and intake of outside air and exhausting of heat which may be generated by the equipment; said support frame being mountable on a surface; an openable cover attached to said frame; an external opening at least along the top of the enclosure, said opening configured to allow the free passage of liquids and air therethrough; a liquid passageway in fluid communication with said external opening and which connects external opening on the top to like openings on the bottom, thereby defining a liquid pathway through the enclosure; said liquid passageway configured to permit passage of liquids, under force of gravity from said top to said bottom; said opening in communication with an air passageway which follows a path which, at least a portion thereof requires air passing therethrough to follow a path against the force of gravity; said air passageway including an internal opening located inside said enclosure offset from said external opening; a separation wall at least partially disposed between said air and liquid passageways, thereby forming wet and dry passageways; said wet passageway having an exit at the bottom of said enclosure and said dry passageway connecting said internal opening to the space provided for said equipment; so that air entering said external openings is forced to follow a path which at least partway requires the flow of air to be counter to the force of gravity, thereby separating it from liquid, while liquids entering said external apertures follow a gravitational path through said liquid passage way and out of the bottom of the enclosure without touching the equipment.

A further aspect of the disclosure includes active ventilation by at least one fan located outside the space defined for the equipment but in the dry passageway.

A further aspect of the disclosure is wherein the opening is a first channel extending generally along the length of the top side of the enclosure.

A further aspect of the disclosure is wherein the opening includes a first channel extending generally along the length of the top and one side.

A further aspect of the disclosure is wherein the opening includes a first channel extending generally along the length of the top, bottom and both sides.

A further aspect of the disclosure includes a secondary overflow channel adjacent said first channel, said overflow channel includes a liquid passageway separate draining at the bottom of the enclosure.

A further aspect of the disclosure is wherein the secondary channel includes a baffle within said enclosure to direct liquid flow adjacent said support frame.

A further aspect of the disclosure is a water impervious ventilated enclosure having a top, bottom and sides, and defining a dry ventilated space for equipment therein having an support frame for receiving equipment requiring protection from liquid contact and intake of outside air and exhausting of heat which may be generated by the equipment; said support frame being mountable on a surface; an openable cover hingeably attached to said frame; a channel forming an external opening in the enclosure, at least along the top and one of the sides of the enclosure, said opening configured to allow the free passage of liquids and air therethrough into the space encompassed by the enclosure; a liquid passageway in fluid communication with said external opening and which connects external opening to like openings on a side opposite the opening, thereby defining at least one liquid pathway through the enclosure; said liquid passageway configured to permit passage of liquids, under force of gravity from said top to said bottom; said opening also in communication with an air passageway to said defined space containing the equipment, which follows a path which, at least a portion thereof, requires air passing therethrough to follow a path against the force of gravity; said air passageway including an internal opening located inside said enclosure, said internal opening being in a plane generally parallel with said external opening but laterally offset therefrom, to prevent entry of liquids; a separation wall at least partially disposed between said air and liquid passageways, thereby forming wet and dry passageways; said wet passageway having an exit at the bottom of said enclosure and said dry passageway connecting said internal opening to the space provided for said equipment; so that air entering said external openings is forced to follow a path which at least partway requires the flow of air to be counter to the force of gravity, thereby separating it from liquid, while liquids entering said external apertures follow a gravitational path through said liquid passage way and out of the bottom of the enclosure without touching the equipment.

A further aspect of the disclosure is includes a strike plate located inside the enclosure in alignment with the gravitational flow of liquid through the external opening and wherein said internal air passage opening is located above the strike plate, relative the path of gravity, so liquids are unlikely to enter the air passage after encountering the strike plate.

A further aspect of the disclosure is the strike plate is canted in a direction which urges liquids to flow toward the wet passageway after encountering the strike plate.

A further aspect of the disclosure includes a transparent opening in the cover to allow viewing of the equipment.

A further aspect of the disclosure is a method of protecting equipment from rain while providing ventilation therefore, comprising the steps of: providing an enclosure for the equipment which is generally fluid impervious except for defined openings in the top and bottom thereof; providing a first liquid passageway which connects the openings on the top and bottom; providing a second air passageway which connects at least some of the openings in the top to the space containing the equipment, said air passageway following a path which at least partway along its path, forces the air to flow in a direction against the force of gravity; providing a barrier between the two pathways so that fluid, which must follow the path of gravity will be prevented from entering the space provided for the equipment, while said space is ventilated through the air passageway.

### BRIEF DESCRIPTION OF THE SEVERAL VIEWS OF THE DRAWINGS

FIG. 1 is a schematic view of a the front of an enclosure containing a video display;

FIG. 2 is a perspective view of an enclosure having a hinged from panel a wall mountable support frame and an active ventilation system;

FIG. 3 is a side plan view of FIG. 2;

FIG. 4 is sectional view along lines 4-4 of FIG. 1 of a corner of the enclosure with portion broken away to show passageways and with arrows illustrating the air and liquid passageways;

FIG. 5 is a sectional view along lines 5-5 of FIG. 1 showing a typical sidewall construction of the enclosure; and

FIG. 6 is partial perspective view of the enclosure with portions broken away to illustrate passageways

### DETAILED DESCRIPTION OF THE INVENTION

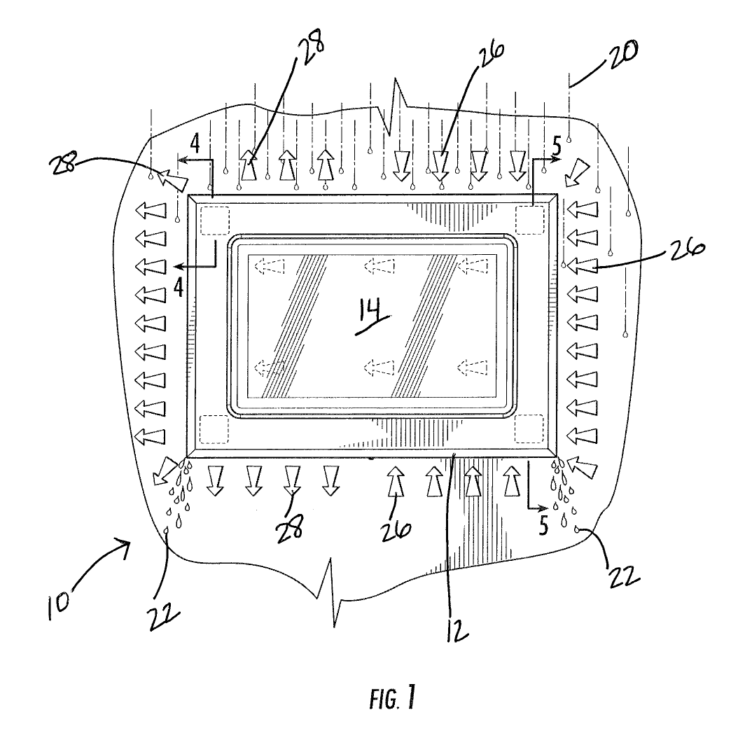

FIG. 1 is a schematic representation of an enclosure 10 having a cover portion 12 and shown with a preferable transparent window 14. For purposes of convenience, the equipment enclosed is a flat screen video monitor which is a typical but not exclusive application for this device. In such case the window represents the viewing port thru which the screen can be seen. For such equipment, protection against liquids, such as rain, and temperature control of the equipment is essential. The term “waterproof” is intended to mean protection against liquid incursion but not necessarily capable of submersion into water.

Rain or other forms of liquid are represented by drops 20 at the top edge of the enclosure with drainage liquid shown at the bottom as drops 22. It should be appreciated, that, while the enclosure is shown in the landscape (horizontal) orientation, in the preferred embodiment, it may be “letter” (vertical) or askew and still function as desired. This allows a single design to handle different applications.

Arrows 26 represent air flow into the enclosure with arrows 28 representing outflow. In and out airflow is shown for the top, bottom and sides, but this is only in the preferred configuration.

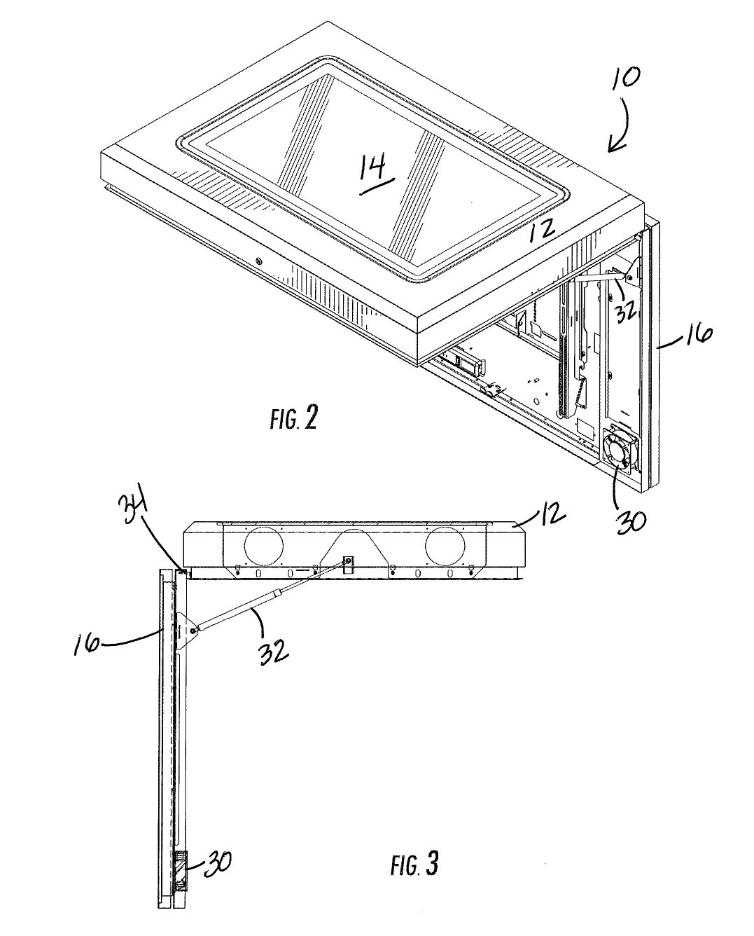

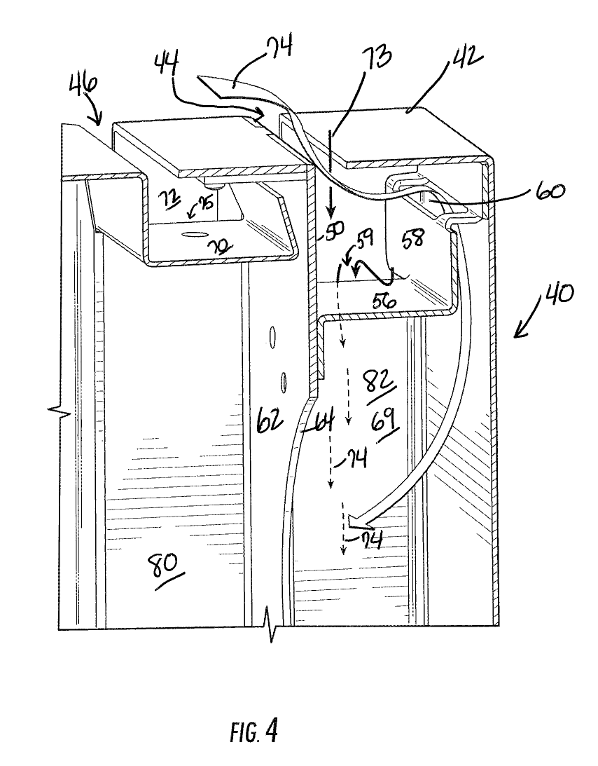

FIGS. 2-3 illustrate further features. The cover is hingeably attached to the back portion or plate 16 but an upper hinged 34 and the cover is supported in position by a pneumatic cylinder which also dampens the movement of the cover which could be relatively heavy depending on the size of the enclosure. Note that the cover could have multiple detachable hinges so that it could be hinged from the top or sides or when in a different orientation, the top (or side) may always be the hinge point. This may be helpful for heavy enclosures.

It will be appreciated that alternate embodiments do not require the hinge at the top and indeed in “letter” configuration, it could be on the side. It is also possible to suspend the cover by hooks and have it completely removeable.

Ventilator fans 30 illustrate active ventilation, but it may not be required depending on the head generation or sensitivity of the enclosed device. Since this is likely an outdoor application, heat from sun an important consideration in ventilation. In the preferred embodiment the fan(s) are located outside the space defined for the equipment but in the dry flow path for air. This is a significant advantage because it allows for maximum space utilization. The fan in this case, is located at the bottom of the enclosure and used to draw air into the space and exhaust it from the top, opposite to what is shown by arrow 74. This configuration takes advantage of natural convection of warm air.

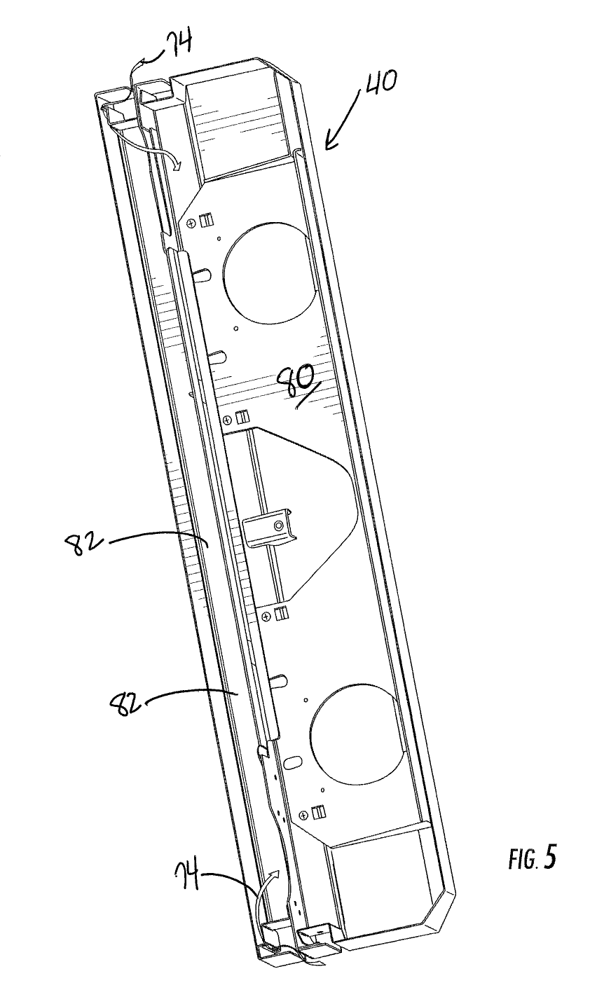

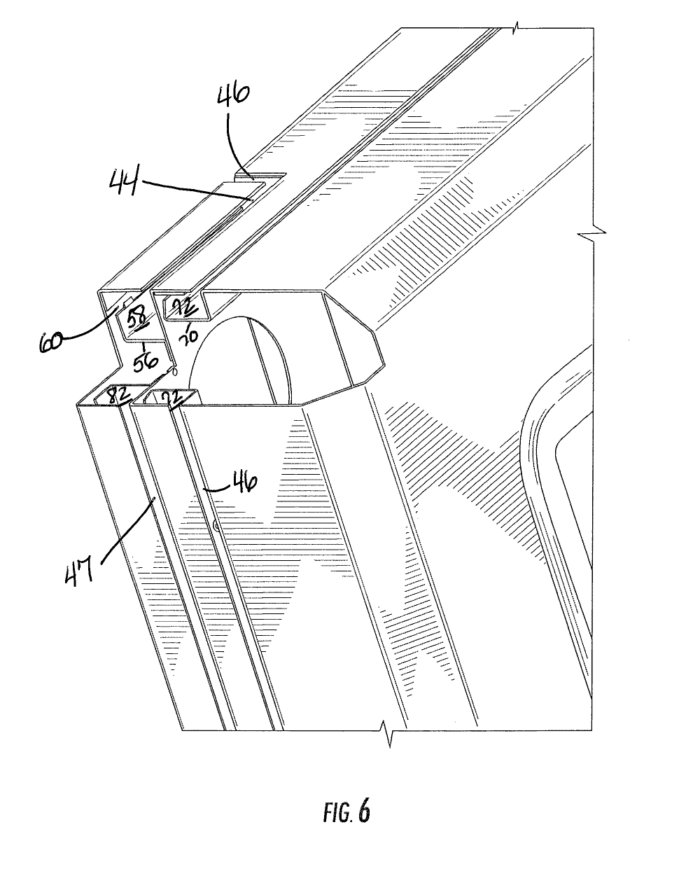

FIGS. 4, 5 and 6 illustrate the channeling arrangement which separates liquid from air.

FIG. 4 is a perspective with portions broken away of one corner of the enclosure. Note that the channels are located in the cover portion. Arrows 74 illustrates the preferred path for airflow, while arrows 73 (darker) show the preferred liquid path. Note that while air and liquid enter any of the openings 44 (which are preferably a single opening or a channel along most or all of the length of one side, liquids follow the path of gravity, while air is able to enter opening 44 (or exit—the flow can be in the opposite direction), and flow against the force of gravity and thus be separated from liquid.

Following the pathways for liquid and air (gasses), both enter thru a plurality of openings or channels 44 which are located on at least two adjacent and preferably 4 sides. Having them on two adjacent sides means that the enclosure can be used in letter or landscape orientation. FIG. 6 illustrates one such corner.

Fluids entering aperture 44 enter a chamber (space) bounded by various sidewalls including 42, 50, 56,and 58. Sidewall or baffle 56 is a “strike plate” disposed in the direct gravitational path from the external opening, which blocks liquid from flowing directly downwardly and causes the flow to a gap 59 between the baffle and a channel which ultimately exits the enclosure at the bottom (see droplets 22 in FIG. 1). It is possible to encourage the flow of liquid toward this gap 59 by canting (angling or tilting) the surface toward the gap so that the natural water flow is toward the gap.

The bracket formed of walls 56 and 58 also includes an internal opening or gap 60 for air flow. Aperture 60 should be above plate 56 or gap 59 (with respect to gravitational force) and preferably high enough that there will be little splash of liquid into the air flow path illustrated by arrow 74. In the preferred embodiment, opening 60 is in parallel planes but laterally offset from the opening or channel 44. This offset is to prevent direct entry of liquid or rain. Notice that arrows 74 are shown in broken lines when they illustrate liquid obscured from view by wall 82 in passage 59 (behind wall 82). This creates a wet chamber 59 and a dry chamber 69 on either side of wall 82.

Note that in the preferred embodiment, the liquid flow is along the back wall 82 leaving space below wall 56 to be a common carrier of liquid and air, but not commingled. The liquids are forced toward the back wall 82.

Wall 62 which separates the space which holds the equipment from the liquid/air flow channels, includes a divider wall 62 which has an opening created by cut away 64.

Secondary openings 46 with associated overflow channels 72 formed by bracket 70 provide additional liquid flow pathways. Channels 72 are optional but provide a way to drain liquids which overflow opening 46 and might fill the space bounded by walls 56 and 58. Bracket 70, in the preferred embodiment, is preferably provided with a gap 75 to allow liquid passage in a channel behind wall 80 (see FIG. 4) so that liquid passes from top to bottom along the inside wall 80 in a channel (not visible) there-behind and adjacent the support frame 16.

Therefore, one element of the disclosure is the concept of creating a pathway for air flow which must, for at least a portion of the passage, define gravitational forces, something which gasses are more likely to do than liquids and to separate the flow of air and liquids on either side of a baffle wall (such as 80 and 82) so that the enclosure is very compact yet provides for a large air volume flow rate and still segregates liquids. The air volume must necessarily be much larger than the liquid volume as very hot equipment (or sun drenched enclosures) may require large volumes of air movement without the need for massive and noisy ventilator fans. Noise is a problem because the equipment may be a video screen and sound is a feature of its function.

The preferred embodiment also includes means, as described, for separating liquids and air along all sides of the enclosure, and at least two adjacent sides. In the 4 sided version, the enclosure can be used in any orientation. In the two sided version, there are two sides which will have this separation built in.

This disclosure also includes a method enclosing equipment which must be temperature controlled and kept dry which includes some or all of the steps of providing an enclosure around the equipment, providing at least one opening in the top to provide intake or exhaust of air, providing a gravitational passageway for liquids which may enter the opening, such that the liquids will follow a gravitational path out of the enclosure without coming in contact with the equipment; providing an air passage way utilizing the same opening and including a pathway into the space containing the equipment but separated from the liquid passageway by a portion of the passage which requires the flow to follow a path against the force of gravity; thereby insuring separation of liquids and air.

The description of the invention and its applications as set forth herein is illustrative and is not intended to limit the scope of the invention. Variations and modifications of the embodiments disclosed herein are possible, and practical alternatives to and equivalents of the various elements of the embodiments would be understood to those of ordinary skill in the art upon study of this patent document. These and other variations and modifications of the embodiments disclosed herein may be made without departing from the scope and spirit of the invention.

We claim:

1. A water impervious ventilated enclosure having a top, bottom and sides, and a space for equipment therein comprising:
a) an support frame for receiving equipment requiring protection from liquid contact and intake of outside air and exhausting of heat which may be generated by the equipment; said support frame being mountable on a surface;
b) an openable cover attached to said frame;
c) an external opening at least along the top of the enclosure, said opening configured to allow the free passage of liquids and air therethrough;
d) a liquid passageway in fluid communication with said external opening and which connects external opening on the top to like openings on the bottom, thereby defining a liquid pathway through the enclosure; said liquid passageway configured to permit passage of liquids, under force of gravity from said top to said bottom;
e) said opening in communication with an air passageway which follows a path which, at least a portion thereof requires air passing therethrough to follow a path against the force of gravity;
f) said air passageway including an internal opening located inside said enclosure offset from said external opening;
g) a separation wall at least partially disposed between said air and liquid passageways, thereby forming wet and dry passageways; said wet passageway having an exit at the bottom of said enclosure and said dry passageway connecting said internal opening to the space provided for said equipment;
so that air entering said external openings is forced to follow a path which at least partway requires the flow of air to be counter to the force of gravity, thereby separating it from liquid, while liquids entering said external apertures follow a gravitational path through said liquid passage way and out of the bottom of the enclosure without touching the equipment.

2. The enclosure of claim 1 further including active ventilation by at least one fan located outside the space defined for the equipment but in the dry passageway.

3. The enclosure of claim 1 wherein said opening is a first channel extending generally along the length of the top side of the enclosure.

4. The enclosure of claim 1 wherein said opening includes a first channel extending generally along the length of the top and one side.

5. The enclosure of claim 1 wherein said opening includes a first channel extending generally along the length of the top, both and both sides.

6. The enclosure of claim 3 further including a secondary overflow channel adjacent said first channel, said overflow channel include a liquid passageway separated draining at the bottom of the enclosure.

7. The enclosure of claim 6 wherein said secondary channel includes a baffle within said enclosure to direct liquid flow adjacent said support frame.

8. A water impervious ventilated enclosure having a top, bottom and sides, and defining a dry ventilated space for equipment therein comprising:
a) an support frame for receiving equipment requiring protection from liquid contact and intake of outside air and exhausting of heat which may be generated by the equipment; said support frame being mountable on a surface;
b) an openable cover hingeably attached to said frame;
c) a channel forming an external opening in the enclosure, at least along the top and one of the sides of the enclosure, said opening configured to allow the free passage of liquids and air therethrough into the space encompassed by the enclosure
d) a liquid passageway in fluid communication with said external opening and which connects external opening to like openings on a side opposite the opening, thereby defining at least one liquid pathway through the enclosure; said liquid passageway configured to permit passage of liquids, under force of gravity from said top to said bottom;
e) said opening also in communication with an air passageway to said defined space containing the equipment, which follows a path which, at least a portion thereof, requires air passing therethrough to follow a path against the force of gravity;
f) said air passageway including an internal opening located inside said enclosure, said internal opening being in a plane generally parallel with said external opening but laterally offset therefrom, to prevent entry of liquids;
g) a separation wall at least partially disposed between said air and liquid passageways, thereby forming wet and dry passageways; said wet passageway having an exit at the bottom of said enclosure and said dry passageway connecting said internal opening to the space provided for said equipment;
so that air entering said external openings is forced to follow a path which at least partway requires the flow of air to be counter to the force of gravity, thereby separating it from liquid, while liquids entering said external apertures follow a gravitational path through said liquid passage way and out of the bottom of the enclosure without touching the equipment.

9. The enclosure of claim 8 further including a strike plate located inside the enclosure in alignment with the gravitational flow of liquid through the external opening and wherein said internal air passage opening is located above the strike plate, relative the path of gravity, so liquids are unlikely to enter the air passage after encountering the strike plate.

10. The enclosure of claim 9 wherein the strike plate is canted in a direction which urges liquids to flow toward the wet passageway after encountering the strike plate.

11. The enclosure of claim 8 further including a transparent opening in the cover to allow viewing of the equipment.

12. A method of protecting equipment from rain while providing ventilation therefore, comprising the steps of:
a) providing an enclosure for the equipment which is generally fluid impervious except for defined openings in the top and bottom thereof
b) providing a first liquid passageway which connects the openings on the top and bottom;
c) providing a second air passageway which connects at least some of the openings in the top to the space containing the equipment, said air passageway following a path which at least partway along its path, forces the air to flow in a direction against the force of gravity;
d) providing a barrier between the two pathways so that fluid, which must follow the path of gravity will be prevented from entering the space provided for the equipment, while said space is ventilated through the air passageway.
